(19) United States
(12) Patent Application Publication
(10) Pub. No.: US 2025/0216793 A1
(43) Pub. Date: Jul. 3, 2025

(54) METHOD OF CONFIGURING EXTREME ULTRAVIOLET ILLUMINATION SYSTEM AND EXTREME ULTRAVIOLET EXPOSURE METHOD USING THE ILLUMINATION SYSTEM

(71) Applicant: SAMSUNG ELECTRONICS CO., LTD., Suwon-si (KR)

(72) Inventors: Soojung KIM, Suwon-si (KR); Kwangseok Maeng, Suwon-si (KR); Noyoung Chung, Suwon-si (KR); Insung Kim, Suwon-si (KR); Jaehyoung Kim, Suwon-si (KR); Ahyun Park, Suwon-si (KR); Hoyoung Lee, Suwon-si (KR); Hyunjae Cho, Suwon-si (KR)

(73) Assignee: SAMSUNG ELECTRONICS CO., LTD., Suwon-si (KR)

(21) Appl. No.: 18/813,621

(22) Filed: Aug. 23, 2024

(30) Foreign Application Priority Data
Jan. 2, 2024 (KR) 10-2024-0000493

(51) Int. Cl. G03F 7/00; G03F 1/24

(52) U.S. Cl. CPC G03F 7/70125; G03F 1/24; G03F 7/70033; G03F 7/70133; G03F 7/70191; G03F 7/702

(57) ABSTRACT

A method of configuring an extreme ultraviolet (EUV) system may include measuring a phase of an EUV mask, correcting a wavefront based on the phase of the EUV mask, optimizing a cost function, and configuring an EUV illumination system with a combination of EUV light sources based on the optimized cost function.

### CROSS-REFERENCE TO RELATED APPLICATION

This application is based on and claims priority under 35 U.S.C. § 119 to Korean Patent Application No. 10-2023-0000493, filed on Jan. 2, 2024, in the Korean Intellectual Property Office, the disclosure of which is incorporated by reference herein in its entirety.

### BACKGROUND

Example embodiments of the disclosure relate to a method of configuring an extreme ultraviolet (EUV) illumination system and an EUV exposure method using the EUV illumination system.

As the line widths of semiconductor circuits become increasingly smaller, light sources with shorter wavelengths have been used. For example, EUV light has been used as an exposure light source and the number of layers that use EUV light as an exposure light source is increasing. Due to the absorption characteristics of EUV light, reflective EUV masks may be generally used in an EUV exposure process. Additionally, the illumination optics for transmitting EUV light to an EUV mask and the projection optics for projecting EUV light reflected by an EUV mask to an exposure target may include a plurality of mirrors.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a method of configuring an extreme ultraviolet (EUV) illumination system and an EUV exposure method using the EUV illumination system.

Additional aspects will be set forth in part in the description which follows and, in part, will be apparent from the description, or may be learned by practice of the presented embodiments.

According to an aspect of an example embodiment, a method of configuring an EUV system may include measuring a phase of an EUV mask, correcting a wavefront based on the phase of the EUV mask, optimizing a cost function, and configuring an EUV illumination system with a combination of EUV light sources based on the optimized cost function.

According to an aspect of an example embodiment, a method of configuring an EUV system may include measuring a phase of an EUV mask, determining a contrast loss based on the phase of the EUV mask, performing a first correction of a wavefront based on the contrast loss, optimizing a cost function, performing a second correction of the wavefront, and configuring an EUV illumination system with a combination of EUV light sources based on the optimized cost function.

According to an aspect of an example embodiment, an EUV exposure method may include preparing an EUV mask, configuring an EUV illumination system corresponding to the EUV mask, and performing EUV exposure on a wafer using the EUV illumination system, where the configuring of the EUV illumination system may include measuring a phase of the EUV mask, performing a first correction of a wavefront based on the phase of the EUV mask, optimizing a cost function, and configuring the EUV illumination system with a combination of EUV light sources based on the optimized cost function.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a flowchart illustrating a method of configuring an extreme ultraviolet (EUV) illumination system according to one or more embodiments;

FIG. 2 is a diagram illustrating an EUV illumination system used in conjunction with the method of configuring the EUV illumination system of FIG. 1, according to one or more embodiments;

FIG. 3 is a cross-sectional view illustrating a structure of an EUV mask according to one or more embodiments;

FIG. 4 is a cross-sectional view illustrating a structure of an EUV mask according to one or more embodiments;

FIG. 5 is a diagram illustrating a phase of each area of an EUV mask according to one or more embodiments;

FIG. 6 is a flowchart illustrating a method of determining contrast loss according to one or more embodiments;

FIG. 7 is a diagram illustrating a method of determining pattern shift according to one or more embodiments;

FIGS. 8 and 9 are diagrams illustrating a placement of light sources on a pupil plane considering the Zernike polynomials, according to one or more embodiments;

FIG. 10 is a diagram illustrating a distribution of 0th order diffraction lights of an EUV light source on a pupil plane according to one or more embodiments;

FIG. 11 is a flowchart illustrating an EUV exposure method using an EUV illumination system according to one or more embodiments; and

FIG. 12 is a block diagram of an EUV illumination system according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Operations of a method may be performed in an appropriate order unless explicitly described in terms of order. In addition, the use of all illustrative terms (e.g., etc.) is merely for describing technical ideas in detail, and the scope is not limited by these examples or illustrative terms unless limited by the claims.

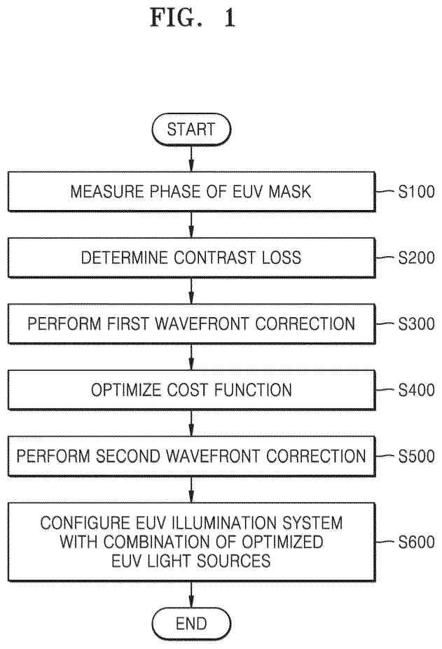

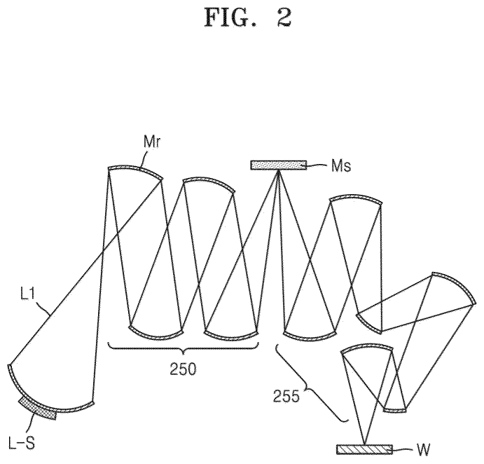

FIG. 1 is a flowchart illustrating a method of configuring an extreme ultraviolet (EUV) illumination system according to one or more embodiments. FIG. 2 is a diagram illustrating an EUV illumination system used in conjunction with the method of configuring the EUV illumination system of FIG. 1, according to one or more embodiments.

Referring to FIGS. 1 and 2, the EUV illumination system may include an EUV light source L-S, a first optical system 250, a second optical system 255, an EUV mask Ms, and a wafer W. The EUV light source L-S may generate and output the EUV light L1 having a high energy density within a range of about 5 nm to about 50 nm. For example, the EUV light source L-S may generate and output the EUV light L1 having a high energy density of about 13.5 nm. The EUV light source L-S may be a plasma-based light source or a synchrotron radiation light source. The plasma-based light source may refer to a light source that generates plasma and uses light emitted by the plasma. The plasma-based light source may include laser-produced plasma (LPP) or discharge-produced plasma (DPP).

The first optical system 250 may include a plurality of mirrors. For example, the first optical system 250 may include 2 to 5 mirrors Mr. However, the number of mirrors in the first optical system 250 is not limited to 2 to 5. The first optical system 250 may be referred to as an EUV illumination optical system or an EUV illumination system. Accordingly, in the method of configuring the EUV illumination system according to one or more embodiments, the EUV illumination system may correspond to the first optical system 250. However, the EUV illumination system may refer to the EUV light source L-S, the first optical system 250, and the second optical system 255.

The first optical system 250 may transmit the EUV light L1 from the EUV light source L-S to the EUV mask Ms. For example, the EUV light L1 from the EUV light source L-S may be incident on the EUV mask Ms on a mask stage through reflection by the mirrors Mr within the first optical system 250. The first optical system 250 may form the EUV light L1 into a curved slit shape and make the EUV light L1 incident on the EUV mask Ms. The curved slit shape of the EUV light may refer to a parabolic two-dimensional curve on the XY plane.

For example, the EUV illumination system may include a dipole illumination system arranged symmetrically with respect to one point. The point may be the center of a pupil plane of the EUV mask Ms. The dipole illumination system may include two light sources pointing in opposite directions. The dipole illumination system may easily control diffraction and interference patterns. The pupil plane may refer to a pupil plane of the EUV mask Ms.

The EUV illumination system may include a plurality of point sources. The EUV point source may be the smallest unit that can be individually turned on/off. The EUV point source may be created by segmenting the EUV illumination system. For example, the EUV illumination system may have partial coherence.

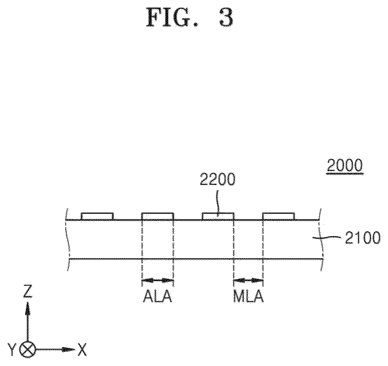

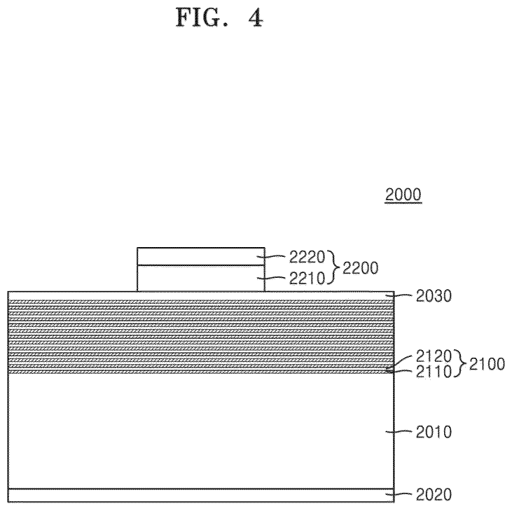

The EUV mask Ms may be a reflective mask having a reflective area and a non-reflective and/or intermediate-reflective area. The EUV mask Ms may include a substrate formed of a low thermal expansion coefficient material (LTEM), such as quartz, a reflective multi-layer film for reflecting EUV light on the substrate, and absorber layers formed on the reflective multi-layer film. The EUV mask Ms is described in more detail with reference to FIGS. 3 and 4.

The EUV mask Ms may reflect the EUV light L1 incident through the first optical system 250 and may make the EUV light L1 incident on the second optical system 255. More specifically, the EUV mask Ms may reflect the EUV light L1 from the first optical system 250 and may structure the EUV light L1 according to the pattern formed by the reflective multi-layer film and the absorber layers on the substrate to make the EUV light L1 incident on the second optical system 255. The EUV light L1 may be structured to include at least second order diffracted light based on the pattern on the EUV mask Ms. The structured EUV light L1 may have information about the pattern on the EUV mask Ms when incident on the 2nd optical system 255 and may be projected through the 2nd optical system 255 onto an EUV exposure target (that is, the wafer W). The second optical system 255 may be referred to as an EUV projection optical system. The second optical system 255 may include a plurality of mirrors. For example, the second optical system 255 may include 4 to 8 mirrors. However, the number of mirrors in the second optical system 255 is not limited to 4 to 8.

The EUV mask Ms may be placed on the mask stage. By moving the mask stage, the EUV mask Ms may be moved in a first horizontal direction (e.g., X direction), a second horizontal direction (e.g., Y direction), or a vertical direction (e.g., Z direction), and may be rotated with respect to the first horizontal direction, the second horizontal direction, or the vertical direction. The wafer W, which is the EUV exposure target, may be placed on a wafer stage. By moving the wafer stage, the wafer W may be moved in the first horizontal direction (e.g., X direction), the second horizontal direction (e.g., Y direction), or the vertical direction (e.g., Z direction) and may be rotated with respect to the first horizontal direction, the second horizontal direction, or the vertical direction.

In FIG. 2, a direction parallel to a main surface of the wafer W may be defined as the horizontal direction (e.g., X direction and/or Y direction) and a direction perpendicular to the horizontal direction may be defined as the vertical direction (e.g., Z direction).

In the method of configuring the EUV illumination system according to one or more embodiments, the phase of the EUV mask Ms may be first measured in operation S100. As described above, the EUV mask Ms may cause the EUV light L1 to be incident on the second optical system 255. A method of measuring the phase of the EUV mask Ms is described with reference to FIGS. 3 to 5.

FIG. 3 is a cross-sectional view illustrating a structure of an EUV mask according to an embodiment. FIG. 4 is a cross-sectional view illustrating a structure of an EUV mask according to one or more embodiments.

Referring to FIGS. 3 and 4, the EUV mask Ms may include a mask substrate 2010, a back coating layer 2020, a multi-layer 2100, a capping layer 2030, and absorber layers 2200.

The mask substrate 2010 may be formed of an LTEM. For example, the mask substrate 2010 may include a silicon substrate or a quartz substrate.

The back coating layer 2020 may be formed on a lower surface of the mask substrate 2010 and the multi-layer 2100 may be formed on an upper surface of the mask substrate 2010. The back coating layer 2020 may be formed of a conductive material, such as metal.

The multi-layer 2100 may have a structure in which two types of different material layers are alternately stacked. For example, the multi-layer 2100 may have a structure in which a silicon layer 2110 (Si layer) and a molybdenum layer 2120 (Mo layer) are alternately stacked. In one or more embodiments, the multi-layer 2100 may include about 40 to about 60 bilayers of the Si layer and the Mo layer. Additionally, the silicon layer 2110 and molybdenum layer 2120 constituting the multi-layer 2100 may have thicknesses of about 3 nm and about 4 nm, respectively. The multi-layer 2100 may generally be formed on the mask substrate 2010, such as a silicon substrate or a quartz substrate.

The capping layer 2030 may be formed on the multi-layer 2100. The absorber layers 2200 may be formed on the capping layer 2030. In other words, the capping layer 2030 may be positioned between the absorber layers 2200 and the multi-layer 2100. The capping layer 2030 may include one or more material layers and may protect the multi-layer 2100. For example, the capping layer 2030 may include ruthenium. The material of the capping layer 2030 is not limited to ruthenium.

The absorber layers 2200 may be disposed on the multi-layer 2100. Additionally, the absorber layers 2200 may have a predetermined pattern shape on the multi-layer 2100, as shown in FIG. 3. For example, the absorber layers 2200 may have a line and space pattern shape in which the absorber layers 2200 are spaced apart from each other in the first horizontal direction (e.g., X direction) and extend in the second horizontal direction (e.g., Y direction). The pattern shape of the absorber layers 2200 is not limited to the line and space pattern shape. The pattern shape of the absorber layers 2200 may have repeatability to facilitate phase calculation. However, the pattern shape of the absorber layers 2200 is not limited thereto.

The absorber layers 2200, which are layers that absorb EUV light, may include tantalum nitride (TaN), tantalum (Ta), titanium nitride (TiN), or titanium (Ti). The material of the absorber layers 2200 is not limited to the materials described above.

The absorber layer 2200 may include an absorbent body 2210 and an anti-reflective coating (ARC) layer 2220. The absorbent body 2210, which is a layer that absorbs EUV light, may include TaN, Ta, TiN, or Ti. The material of the absorbent body 2210 is not limited to the materials described above. The ARC layer 2220 may prevent reflection of incident EUV light and may be omitted in one or more embodiments. According to one or more embodiments, the ARC layer 2220 may include, for example, silicon nitride (SiN), silicon oxide (SiO), silicon oxynitride (SiON), molybdenum silicon nitride (MoSiN), molybdenum silicon oxide (MoSiO), molybdenum silicon oxynitride (MoSiON), and TiN. According to one or more embodiments, the ARC layer 2220 may include an amorphous carbon film, an organic ARC, an inorganic ARC, and the like.

Hereinafter, an exposed portion of the multi-layer 2100 between the absorber layers 2200 may referred to as a multi-layer area MLA and a portion of the absorber layer 2200 may be referred to as an absorber layer area ALA. Due to the characteristics of the multi-layer area MLA being bright and the absorber layer area ALA being dark, the multi-layer area MLA may be referred to as a clear area and the absorber layer area ALA may be referred to as a dark area. The reflectivity (e.g., a first reflectivity) of the multi-layer area MLA may be greater than the reflectivity (e.g., a second reflectivity) of the absorber layer area ALA.

There may be a path difference between EUV light reflected in the multi-layer area MLA and EUV light reflected in the absorber layer area ALA. Due to the path difference, a phase difference in the EUV mask Ms may occur. The phase difference may cause the contrast loss and reduce the reliability of the EUV mask Ms. A method of determining and correcting the contrast loss resulting from the phase difference is described in detail below.

To measure the phase of each area of the EUV mask Ms, the reflected light reflected from each of the multi-layer area MLA and the absorber layer area ALA of the EUV mask Ms may be measured. Each of the reflected light reflected in the multi-layer area MLA and the reflected light reflected in the absorber layer area ALA may be measured by using a detector. The reflected light may include amplitude and phase information.

For example, the EUV light is a type of wave and may be expressed by Equation (1), which is a wave equation.

$$Ψ ( x , t ) = A exp ( i ( kx - wt + ϵ ) ) = A exp ( i φ ) \qquad ( 1 )$$

Herein, x may represent the position, t may represent the time, Ψ(x, t) may represent the EUV light at the position x and the time t, A may represent the amplitude, i may represent the imaginary unit, k may represent the wave number, ω may represent the frequency, and ∈ and φ may represent the phase of EUV light.

Additionally, the electromagnetic field of the EUV light reflected in the multi-layer area MLA and the electromagnetic field of the EUV light reflected in the absorber layer area ALA may be expressed by Equation (2) below.

$${E}_{1} = {E}_{{x}_{1}} exp ( i \times {φ}_{{x}_{1}} ) + {E}_{{y}_{2}} exp ( i \times {φ}_{{y}_{1}} ) \qquad ( 2 )$$

$${E}_{2} = {E}_{{x}_{2}} exp ( i \times {φ}_{{x}_{2}} ) + {E}_{{y}_{2}} exp ( i \times {φ}_{{y}_{2}} )$$

Herein, E₁ may represent the electromagnetic field of the EUV light reflected in the multi-layer area MLA, E₂ may represent the electromagnetic field of the EUV light reflected in the absorber layer area ALA, x₁, y₁ may represent the coordinates of the multi-layer area MLA, and x₂, y₂ may represent the coordinates of the absorber layer area ALA.

Based on Equation (2) above, the phase of the EUV mask Ms may be expressed by Equation (3) below.

$$phase = {cos}^{- 1} [ \frac{\{ {E}_{{x}_{1}} \times {E}_{{x}_{2}} \times cos ( {φ}_{{x}_{1}} - {φ}_{{x}_{2}} ) + {E}_{{y}_{1}} \times {E}_{{y}_{2}} \times cos ( {φ}_{{y}_{1}} - {φ}_{{y}_{2}} ) \}}{( 2 \times \sqrt{{I}_{1} + {I}_{2}} )} ] \qquad ( 3 )$$

$$where , {I}_{1} = \sqrt{{{E}_{{x}_{1}}}^{2} + {{E}_{{y}_{1}}}^{2}} , {I}_{2} = \sqrt{{{E}_{{x}_{2}}}^{2} + {{E}_{{y}_{2}}}^{2}}$$

Herein, phase may represent the phase of the EUV mask Ms, I₁ may represent the intensity of the electromagnetic field of the EUV light reflected in the multi-layer area MLA and I₂ may represent the intensity of the electromagnetic field of the EUV light reflected in the absorber layer area ALA.

Based on Equations (1), (2), and (3) above, the phase of the EUV mask Ms may be measured on the pupil plane of the EUV mask Ms.

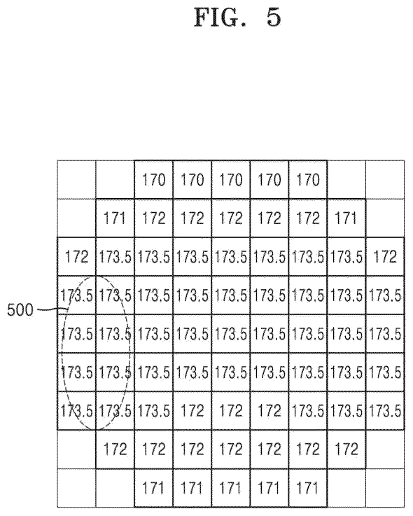

Referring to FIG. 1, after measuring the phase of the EUV mask Ms in operation S100, a contrast loss may be determined in operation S200. The contrast loss may indicate the degree to which the difference between bright and dark areas of an image is reduced. For example, the contrast loss may indicate the degree to which the difference between bright and dark areas of an aerial image is reduced. The operation S200 of determining the contrast loss is described with reference to FIGS. 5, 6 and 7.

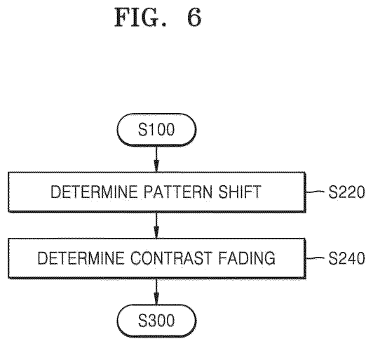

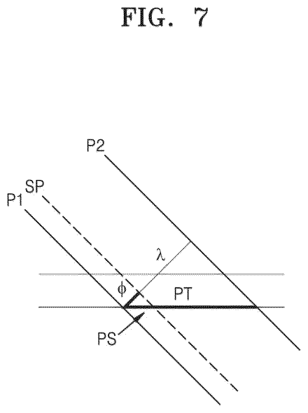

FIG. 5 is a diagram illustrating a phase of each area of an EUV mask according to one or more embodiments. FIG. 6 is a flowchart illustrating a method of determining contrast loss according to one or more embodiments. FIG. 7 is a diagram illustrating a method of determining pattern shift according to one or more embodiments. In FIG. 7, a first pattern P1 and a second pattern P2 are shown as solid lines, and a shifted pattern SP is shown as a dashed line.

Referring to FIGS. 6 and 7, to determine contrast loss, a pattern shift PS value may first be determined in operation S220. The pattern shift PS, also referred to as a pattern placement error (PPE), may result in defective semiconductors.

As shown in FIG. 7, a plurality of patterns adjacent to each other are shown as an example. The first pattern P1 and the second pattern P2 may have a pitch PT and may be spaced apart from each other. The phase of the EUV mask Ms may be different from a normal value and the shifted pattern SP may be spaced apart from the first pattern P1. Considering the nature of similarity, the pattern shift PS value may be determined using Equation (4) below.

$$PT : Ps = 2 π : ϕ , Ps = \frac{PT \times ϕ}{2 π} \qquad ( 4 )$$

Herein, PS may represent the pattern shift, PT may represent the pattern pitch, and ϕ may represent the phase difference. In Equation (4) above, two patterns spaced apart from each other by one wavelength λ are determined to have a phase difference of 2π.

For example, a case where the pattern pitch PT is about 32 nm is described as an example. The pattern pitch PT may refer to a distance between identical phases in the repeated waveform. Accordingly, when the pattern pitch PT is about 32 nm, the distance between the identical phases in the repeated waveform may be about 32 nm.

In each area of the EUV mask Ms in FIG. 5, an area 500 corresponding to the area where the EUV illumination system is positioned is shown with a dashed line. In area 500, the phase of the EUV mask may be about 173.5°. In area 500, the phase of the EUV mask Ms may be shifted by about 6.5°, compared to the normal phase of 180°. When the normal phase is extended to an in-phase state (i.e., when the normal phase is extended to) 360°, the phase difference may be doubled. Additionally, considering that 0th order diffraction light and 1st order diffraction light interfere with each other to create a pattern, the phase difference may be doubled again. That is, the final phase difference may be about 26°. After converting the phase difference into radians and determining the same using Equation (4), the pattern shift PS may be about 2.3 nm.

After determining the pattern shift value in operation S220, a contrast fading value may be determined in operation S240. The contrast fading may be similar to the contrast loss. The contrast fading may be determined using Equation (5) below.

$$CF = cos ( \frac{π \times PS}{PT} ) \qquad ( 5 )$$

Herein, CF may represent the contrast fading, PT may represent the pattern pitch, and PS may represent the pattern shift.

When assigning about 32 nm to the pattern pitch PT and about 2.3 nm to the pattern shift PS, the contrast loss may be determined to be about 10%.

Returning to FIG. 1, after determining the contrast loss in operation S200, the first correction of a wavefront may be performed in operation S300. That is, the wavefront may be corrected for a first time in operation S300. The first correction in operation S300 may be performed based on the pattern shift PS value, the direction of the pattern shift PS, and the contrast loss.

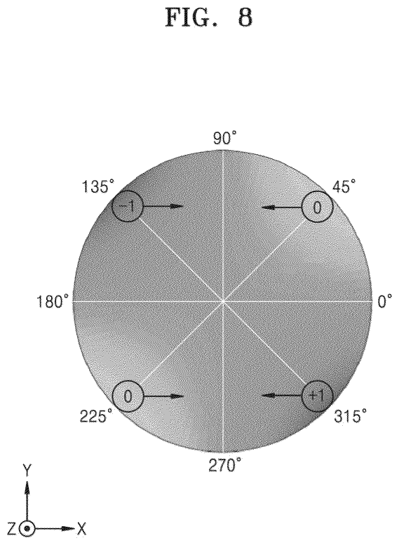

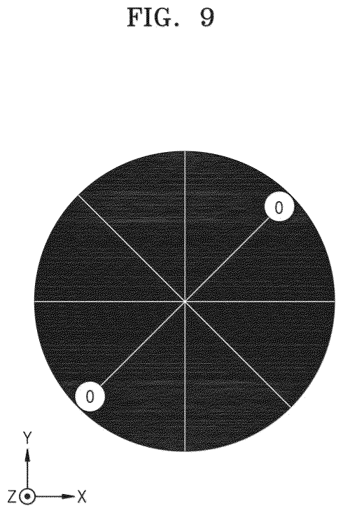

The wavefront function may be expanded into the Zernike polynomials. Afterwards, the aberration may be determined using the terms of the Zernike polynomials and then the wavefront function may be corrected by correcting the aberration. For example, the 6^{th} term of the Zernike polynomials may be used to correct the wavefront. The 6^{th} term of the Zernike polynomials may include a 45° astigmatism component. The process of correcting the wavefront using the Zernike polynomials is described with reference to FIGS. 8 and 9.

FIGS. 8 and 9 are diagrams illustrating a placement of light sources on a pupil plane considering the Zernike polynomials, according to one or more embodiments. FIG. 8 shows −1st order diffraction light, 0th order diffraction light, and 1st order diffraction light, and FIG. 9 shows only the position of the 0th order diffraction light. In FIG. 8, the area marked −1 may be an area where the −1st diffraction light is incident, the area marked 0 may be an area where the 0th order diffraction light is incident, and the area marked +1 may be an area where the 1st order diffraction light is incident. FIGS. 8 and 9 show an axis extending in the first horizontal direction (e.g., X direction) and an axis extending in the second horizontal direction (e.g., Y direction) on the pupil plane. The angle shown in FIG. 8 represents an angle rotated counterclockwise based on the +X direction.

Referring to FIGS. 8 and 9, considering an axis extending in the first horizontal direction (e.g., X direction) and an axis extending in the second horizontal direction (e.g., Y direction), the 0th order diffraction lights from the EUV light source may be incident at the positions, in the first quadrant and the third quadrant, forming about 45° with the axes extending in the first horizontal direction (e.g., X direction) and in the second horizontal direction (e.g., Y direction), respectively. That is, the EUV light sources may be placed at the positions, in the first quadrant and the third quadrant, forming about 45° with the axes extending in the first horizontal direction (e.g., X direction) and in the second horizontal direction (e.g., Y direction), respectively. For example, 0th order diffracted lights from the EUV light source may be incident at points of about 45° and about 225°. The EUV light sources may be symmetrical to each other about the origin of the coordinate system (e.g., the center of the pupil plane).

In one or more embodiments, the 0th order diffraction lights of the EUV light source may be incident at the positions, in the second quadrant and the fourth quadrant, forming 45° with the axes extending in the first horizontal direction (e.g., X direction) and in the second horizontal direction (e.g., Y direction), respectively. That is, the EUV light sources may be placed at the positions, in the second quadrant and the fourth quadrant, forming about 45° with the axes extending in the first horizontal direction (e.g., X direction) and in the second horizontal direction (e.g., Y direction), respectively. For example, 0th order diffracted lights from the EUV light source may be incident at points of about 135° and about 315°. The EUV light sources may be symmetrical to each other about the origin of the coordinate system (e.g., the center of the pupil plane).

In FIGS. 8 and 9, a direction parallel to a main surface of the pupil plane may be defined as the horizontal direction (e.g., X direction and/or Y direction) and a direction perpendicular to the horizontal direction may be defined as the vertical direction (e.g., Z direction).

In FIGS. 8 and 9, the wavefront may be corrected using the 6^{th} term of the Zernike polynomials but embodiments are not limited thereto. The wavefront may be corrected by various terms of the Zernike polynomials. Additionally, various terms of the Zernike polynomials may be selected depending on the pattern shape.

In FIG. 8, arrows may indicate a direction of the pattern shift (PS in FIG. 7). Accordingly, operation S300 may include correcting the pattern shift (PS in FIG. 7) determined in operation S220 by a direction opposite to the arrow. Additionally, the wavefront may be corrected based on the pattern shift (PS in FIG. 7) value determined in operation S220. The correcting of the wavefront may include correcting the wavefront of the pupil plane of the EUV mask Ms.

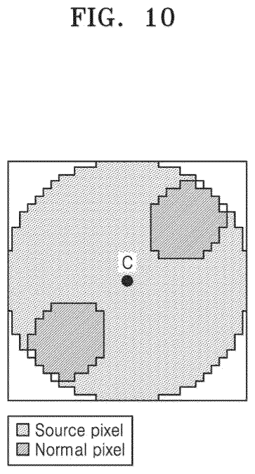

Referring to FIG. 1, after the first correction of the wavefront is performed in operation S300, the cost function may be optimized in operation S400. The cost function may include an edge placement error (EPE), illumination efficiency, and rotational symmetry. The optimizing of the cost function in operation S400 may include minimizing the EPE, maintaining the illumination efficiency at a set value, and/or maintaining the rotational symmetry of EUV illumination. In other words, the combination of EUV light sources may be variously modified and the combination of EUV light sources with the optimized cost function may be searched for and identified. The optimizing of the cost function is explained with reference to FIG. 10.

FIG. 10 is a diagram illustrating a distribution of 0th order diffraction lights of an EUV light source on a pupil plane according to one or more embodiments. In FIG. 10, the pupil plane is divided into a plurality of pixels and may include a source pixel into which the 0th order diffraction lights of the EUV light source are incident and a normal pixel into which the 0th order diffraction lights of the EUV light source are not incident.

Referring to FIG. 10, the illumination efficiency may be determined as shown in Equation (6) below.

$$IE = ( picked source pixel number ) / ( total pixel number ) \qquad ( 6 )$$

Herein, IE may refer to the illumination efficiency, picked source pixel number may refer to the number of pixels in the area where the 0th order diffracted lights of the EUV light source are incident, and total pixel number may refer to the total number of pixels on the pupil plane.

For example, the picked source pixel number may refer to an area occupied by the 0th order diffracted lights of the EUV light source. In other words, the picked source pixel number may refer to an area occupied by the EUV light sources. For example, the illumination efficiency may be set to have a value of about 20%. For example, the illumination efficiency may be set to have a value of about 15% to about 25%.

Additionally, configuring the EUV illumination system to maintain the rotational symmetry may refer to placing the EUV light sources so that the EUV light sources are symmetrical to each other about one point. For example, configuring the EUV illumination system to maintain the rotational symmetry may refer to placing the EUV light sources so that the EUV light sources are symmetrical to each other about the center of the pupil plane.

That is, the optimizing of the cost function in operation S400 may include placing the EUV light sources to minimize the EPE with the EUV light sources placed to be symmetrical to each other and the illumination efficiency set to about 15% to about 25%.

The EPE may be measured by determining the distance between the set position (target position) and the measured position (actual position) of each pattern. Therefore, the EPE may be determined for each of the various placements of the EUV light sources and a combination of EUV light sources that minimizes the EPE may be selected.

Referring to FIG. 1, after the cost function is optimized in operation S400, a second correction of the wavefront may be performed in operation S500. Operation S500, like operation S300, may also be performed based on the Zernike polynomials. Operation S500 may include correcting coefficients of one or more terms of the Zernike polynomials. Operation S500 may be performed based on the set wavefront and the measured wavefront. For example, operation S500 may include searching for and identifying coefficients of the Zernike polynomials that minimize the difference between the set wavefront and the measured wavefront.

Additionally, as described above, correcting the wavefront using the Zernike polynomials may refer to correcting the pupil plane of the projection optical system by correcting a wavefront error component.

To correct the coefficients of one or more terms of the Zernike polynomials, in one or more embodiments, an inverse regression algorithm may be used. The inverse regression algorithm may be an algorithm used to estimate the input variables of a model when the output is known. The second correction of the wavefront may be performed, for example, by interpolating the coefficients of the Zernike polynomials.

Referring to FIG. 1, after performing the second wavefront correction in operation S500, the EUV illumination system may configured with a combination of optimized EUV light sources in operation S600. That is, the EUV illumination system may be configured with the optimized cost function. For example, the first and second corrections of the wavefront may be performed and the EUV light sources with the optimized cost function may be selected.

In the method of configuring the EUV illumination system, the contrast loss may be determined after measuring the phase of the EUV mask Ms, the cost function may be optimized after performing the first correction of the wavefront based on the contrast loss, and the second correction of the wavefront may be performed based on the set wavefront and the measured wavefront. The method of configuring the EUV illumination system may improve the productivity of EUV lithography and may be used universally for various patterns.

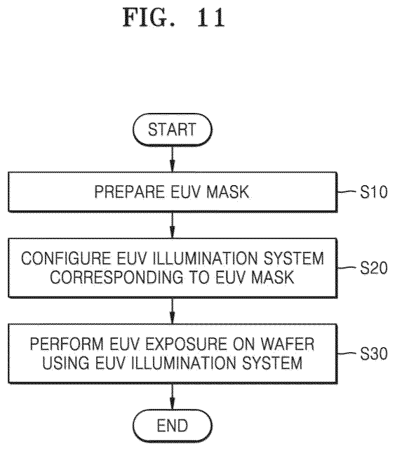

FIG. 11 is a flowchart illustrating an EUV exposure method using an EUV illumination system according to one or more embodiments.

Referring to FIG. 11, in the EUV exposure method using the EUV illumination system according to one or more embodiments (hereinafter referred to as the EUV exposure method), may include preparing an EUV mask Ms in operation S10. The EUV mask herein may be the same as or similar to the EUV mask Ms described with reference to FIGS. 3 and 4. However, preparing the EUV mask Ms may refer to preparing the EUV mask Ms with a specific mask pattern.

After preparing the EUV mask Ms, an EUV illumination system corresponding to the EUV mask may be configured in operation S20. The configuring of the EUV illumination system of operation S20 may include the method of configuring the EUV illumination system of FIG. 1. Therefore, an optimal EUV illumination system may be configured through various operations described in the method of configuring the EUV illumination system of FIG. 1. For example, operation S20 may include measuring the phase of the EUV mask Ms (e.g., operation S100), determining the contrast loss (e.g., operation S200), performing the first correction of the wavefront based on the pattern shift PS and the contrast loss (e.g., operation S300), optimizing the cost function (e.g., operation S400), performing the second correction of the wavefront based on the set wavefront and the measured wavefront (e.g., operation S500), and configuring the EUV illumination system (e.g., operation S600).

In the EUV exposure method, the configuring of the EUV illumination system in operation S20 may include configuring the entire EUV optical system.

After configuring the EUV illumination system, EUV exposure may be performed on the wafer using the EUV illumination system in operation S30. The EUV exposure may refer to projecting EUV light onto an EUV photoresist (PR) layer on a wafer. In one or more embodiments, the EUV exposure may include a development process for the PR layer. A PR pattern may be formed through the development process for the PR layer.

The EUV exposure method may configure an optimal EUV illumination system by including the method of configuring the EUV illumination system of FIG. 1 in the configuring of the EUV illumination system in operation S20. In addition, the optimal EUV exposure may be performed based on the optimal EUV illumination system. Accordingly, the PR pattern that optimally meets the required patterning performance index may be formed on the wafer.

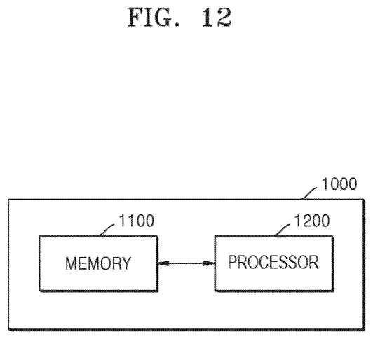

FIG. 12 is a block diagram of an EUV illumination system according to an embodiment.

As shown in FIG. 12, the EUV illumination system 1000 may include a memory 1100 and a processor 1200. However, the configuration shown in FIG. 12 is an example for implementing the embodiments, and other hardware and software configurations may be additionally included in the EUV illumination system 1000 as will be understood to one of ordinary skill in the art from the disclosure herein. According to one or more embodiments, the EUV illumination system 1000 may be implemented in the form of an electronic device.

The EUV illumination system 1000 according to one or more embodiments may be configured to perform operations such as measuring a phase of an EUV mask, correcting a wavefront based on the phase of the EUV mask, optimizing a cost function, and configuring an EUV illumination system with a combination of EUV light sources based on the optimized cost function, as well as other operations described herein.

The memory 1100 may store commands or data related to at least one other component of the EUV illumination system 1000. Also, the memory 1100 may be accessed by the processor 1200, and reading/writing/modifying/deleting/updating of data may be performed by the processor 1200.

The term memory may include the memory 1100, a read-only memory (ROM) or a random access memory (RAM) in the processor 1200, or a memory card (e.g., a micro secure digital (SD) card or a memory stick) mounted in the EUV illumination system 1000. In addition, the memory 1100 may store programs and data for configuring various screens to be displayed on a display area of a display.

According to an example, the memory 1100 may include a non-volatile memory capable of maintaining stored information even if power supply is interrupted, and a volatile memory requiring continuous power supply to maintain stored information. For example, the non-volatile memory may be implemented as at least one of one time programmable ROM (OTPROM), programmable ROM (PROM), erasable and programmable ROM (EPROM), electrically erasable and programmable ROM (EEPROM), mask ROM, or flash ROM, and the volatile memory may be implemented as at least one of dynamic RAM (DRAM), static RAM (SRAM), or synchronous dynamic RAM (SDRAM).

The processor 1200 may be electrically connected to the memory 1100 to control all operations and functions of the EUV illumination system 1000.

As used in connection with various embodiments of the disclosure, the term “module” may include a unit implemented in hardware, software, or firmware, and may interchangeably be used with other terms, for example, logic, logic block, part, or circuitry. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software including one or more instructions that are stored in a storage medium that is readable by a machine. For example, a processor of the machine may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

At least one of the devices, units, components, modules, units, or the like represented by a block or an equivalent indication in the above embodiments including, but not limited to, FIG. 12, may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A method of configuring an extreme ultraviolet (EUV) illumination system, the method comprising:
measuring a phase of an EUV mask;
correcting a wavefront based on the phase of the EUV mask;
optimizing a cost function; and
configuring an EUV illumination system with a combination of EUV light sources based on the optimized cost function.

2. The method of claim 1, wherein the phase of the EUV mask is measured based on an intensity of light reflected from the EUV mask.

3. The method of claim 1, wherein the EUV mask comprises a multi-layer with a first reflectivity and an absorber layer with second reflectivity that is lower than the first reflectivity.

4. The method of claim 1, wherein the wavefront is corrected based on a 6^{th} term of Zernike polynomials.

5. The method of claim 1, wherein the cost function is determined based on an edge placement error (EPE), illumination efficiency, and rotational symmetry.

6. The method of claim 5, wherein the illumination efficiency is determined as a ratio of a number of pixels occupied by the EUV light sources to a total number of pixels on a pupil plane, and
wherein the optimizing of the cost function comprises placing the EUV light sources such that that the illumination efficiency has a constant value.

7. The method of claim 5, wherein the optimizing of the cost function comprises placing the EUV light sources to be symmetrical with respect to a predetermined position.

8. A method of configuring an extreme ultraviolet (EUV) illumination system, the method comprising:
measuring a phase of an EUV mask;
determining a contrast loss based on the phase of the EUV mask;
performing a first correction of a wavefront based on the contrast loss;
optimizing a cost function;
performing a second correction of the wavefront; and
configuring an EUV illumination system with a combination of EUV light sources based on the optimized cost function.

9. The method of claim 8, wherein the determining of the contrast loss comprises:
determining a pattern shift; and
determining a contrast fading based on the pattern shift.

10. The method of claim 9, wherein the pattern shift is determined based on a difference between the phase of the EUV mask and a normal phase.

11. The method of claim 9, wherein the first correction of the wavefront is performed based on the pattern shift and the contrast loss.

12. The method of claim 8, wherein the phase of the EUV mask comprises a phase of an area corresponding to a position where the EUV light sources are placed.

13. The method of claim 8, wherein the performing of the first correction of the wavefront comprises selecting positions of −1st order diffraction light of EUV light, 0th order diffraction light of EUV light, and 1st order diffraction light of EUV light.

14. The method of claim 8, wherein the performing of the second correction of the wavefront comprises identifying coefficients of Zernike polynomials.

15. The method of claim 8, wherein the cost function comprises an edge placement error (EPE), illumination efficiency, and rotational symmetry, and
wherein the optimizing of the cost function comprises:
minimizing the EPE;
maintaining the illumination efficiency at a predetermined value; and
placing EUV illumination to have rotational symmetry.

16. The method of claim 8, wherein the EUV light sources comprise at least one of dipole illumination and a point source.

17. An extreme ultraviolet (EUV) exposure method comprising:
preparing an EUV mask;
configuring an EUV illumination system corresponding to the EUV mask; and
performing EUV exposure on a wafer using the EUV illumination system;
wherein the configuring of the EUV illumination system comprises:
measuring a phase of the EUV mask;
performing a first correction of a wavefront based on the phase of the EUV mask;
optimizing a cost function; and
configuring the EUV illumination system with a combination of EUV light sources based on the optimized cost function.

18. The EUV exposure method of claim 17, wherein the configuring of the EUV illumination system further comprises:
determining a contrast loss based on the phase of the EUV mask; and
performing a second correction of the wavefront.

19. The EUV exposure method of claim 18, wherein the first correction of the wavefront is performed based on a pattern shift and the contrast loss, and
wherein the second correction of the wavefront is performed based on a predetermined wavefront and a measured wavefront.

20. The EUV exposure method of claim 18, wherein the second correction of the wavefront comprises minimizing a difference between a predetermined wavefront and a measured wavefront by identifying coefficients of Zernike polynomials.
